(19) United States
(12) Patent Application Publication
(10) Pub. No.: US 2005/0270599 A1
(43) Pub. Date: Dec. 8, 2005

(54) Image outputting system and image outputting method

(76) Inventor: Shigeyuki Kitazawa, Kawaguchi-shi (JP)

Correspondence Address: CANTOR COLBURN, LLP, 55 GRIFFIN ROAD SOUTH, BLOOMFIELD, CT, 06002, US

(21) Appl. No.: 11/139,345

(22) Filed: May 27, 2005

(30) Foreign Application Priority Data
Jun. 2, 2004 (JP) JP2004-164882

(51) Int. Cl. G03F 3/08

(52) U.S. Cl. 358/518

(57) ABSTRACT

An image outputting system including: an image outputting apparatus for outputting color images onto a recording medium based on image data; a section for storing reference values of color characteristics stipulated for reference colors; a measurement section for measuring values of color characteristics of reference colors outputted by the image outputting apparatus; a section for making judgment of acceptance by comparing measured values of the reference colors measured by the measurement section with the reference values stored in the reference value storing section; a section for storing a result of the judgment of acceptance; and a controller for controlling the image outputting apparatus so that the apparatus outputs onto the recording medium the color images based on image data, and also outputs the result of the judgment of acceptance in a visually verifiable manner.

This application is based on Japanese Patent Application No. 2004-164882 filed on Jun. 2, 2004 in Japanese Patent Office, the entire content of which is hereby incorporated by reference.

### BACKGROUND OF THE INVENTION

The present invention relates to image outputting systems including image outputting apparatuses that output color images based on image data.

Conventionally, during the proofreading process in printing, color proofs which are trial printings are outputted mainly for the three uses of: (1) checking for mistakes inside the work location, that is, in-house proofreading; (2) for outside proofs submitted for verification by the customer placing the order or the designer; and (3) as printing samples submitted as samples of the final printed material to the chief manager of the printing machines.

Further, during proofreading, using such color proofs, inspection is made to check for any mistakes in the layout of the original film, or for any mistakes in the color, or for any mistakes in the spelling of the text, etc., thereby verifying in advance the finish of the printed material, and then making adjustments at the time of printing in order to match the printing colors to the colors of the print sample.

It is desirable that the color tones or densities of the color proof outputted by the outputting apparatus for these purposes satisfy some specific standards. In this context there are some methods of carrying out color management so that the output colors of the target outputting apparatus satisfy the specific standards, for example, by providing the ICC profile for carrying out the color management of the outputting apparatus such as a printing machine or printer based on the result of color measurement of color patches of the outputting apparatus which is the target for acceptance (see, for example, Patent Document 1).

Patent Document 1: Japanese Unexamined-Patent Application Laid-Open No. 2003-46794

However, even if color management such as the one described above is carried out, it is not possible to judge whether or not an above type of color management is being made for an outputting apparatus by merely looking at the output materials such as a color proof. Conventionally, it was necessary to see separately recorded materials in order to judge whether or not color management is being carried out.

Further, even when it was possible to judge that the apparatus is an outputting apparatus whose color management is being carried out, there are cases when the output colors would have changed due to changes with time, and hence it was necessary to judge when it is necessary to carry out the operations for the above type of color management, and it was not possible conventionally to make such judgment easily.

### SUMMARY OF THE INVENTION

The present invention was made with the above-described current state in view, and the purpose of the present invention is to provide an image outputting system and an image forming method that permits easy judgment of whether or not color management is being carried out, by carrying out judgment of whether or not the output colors of an outputting apparatus satisfy the stipulated standards and outputting the result of such judgment in a visually verifiable manner on the output material such as a color proof.

The above problems can be solved by the embodiments having the following configurations.

(1) An image outputting system having an image outputting apparatus that outputs to a recording medium color images based on image data, and with the feature that said system comprises a reference value storing section that stores the reference values of color characteristics stipulated for reference colors, a measurement section that measures the values of color characteristics of reference colors output by said image outputting apparatus, a pass/fail judgment (acceptance judgment) section that makes acceptance judgment by comparing the measured values of said reference colors measured using said measurement section with the reference values stored inside said reference value storing section, a judgment result storing section that stores the result of said acceptance judgment, and an image output control section that controls said image outputting apparatus so that not only color images are outputted based on image data to said recording medium but also said stored acceptance judgment result is outputted in a visually verifiable manner.

### BRIEF DESCRIPTION OF THE DRAWINGS

FIG. 1: This is a functional block diagram showing the system configuration of the image outputting system in the first preferred embodiment according to the present invention.

FIG. 2: This is an explanatory diagram showing the configuration of color patches.

FIG. 3: This is a diagram showing an example of the color references stored in the color reference value storing section shown in FIG. 1.

FIG. 4: This is a flowchart showing the procedure of making the acceptance judgment of output colors according to the present invention.

FIG. 5: This is a diagram showing an example of the screen displayed in the display section of the control device shown in FIG. 1.

FIG. 6: This is a flowchart showing the image outputting procedure according to the present invention.

FIG. 7: This is a diagram showing an example of the screen displayed in the display section of the work terminal shown in FIG. 1.

FIG. 8: This is a diagram showing an example of the output by the image outputting system according to the present invention.

FIG. 9: This is a functional block diagram showing the system configuration of the image outputting system in the second preferred embodiment according to the present invention.

FIG. 10: This is a diagram showing an example of the color references stored in the color reference value storing section shown in FIG. 9.

FIG. 11: This is a flowchart showing the procedure of making the acceptance judgment of output colors according to the second preferred embodiment of the present invention.

FIG. 12: This is a diagram showing an example of the result of acceptance judgment stored in the judgment result storing section shown in FIG. 9.

FIG. 13: This is a flowchart showing the image outputting procedure according to the second embodiment of the present invention.

### DETAILED DESCRIPTION OF THE PREFERRED EMBODIMENT

The above problems can also be solved by embodiments having the following configurations.

(2) An image outputting system having an image outputting apparatus that outputs to a plurality of types of recording media color images based on image data, and with the feature that said system comprises a reference value storing section that stores the reference values of color characteristics stipulated regarding the reference colors for each type of said recording media, a measurement section that measures the values of color characteristics of reference colors outputted by said image outputting apparatus to each type of said recording media, a acceptance judgment section that makes acceptance judgment by comparing the measured values of said reference colors for each type of said recording media measured using said measurement section with the reference values for each type of said recording media stored inside said reference value storing section, a judgment result storing section that stores the results of said acceptance judgment while establishing correspondence between said acceptance judgment results and the types of said recording media, and an image output control section that controls said image outputting apparatus so that not only color images are outputted based on image data to any one type among a pluralities of types of said recording media but also said stored acceptance judgment result for the type of said recording media used is outputted in a visually verifiable manner.

(3) Said judgment result storing section has the feature that it further stores the associated information related to said acceptance judgment decision result while establishing its correspondence, and said image output control section carries out control of said image outputting apparatus so that, in addition to said acceptance judgment result, said associated information is also outputted in a visually verifiable manner.

(4) Said associated information has the feature that it is at least one or a plural number among the date and time at which acceptance judgment was made, the measured values used for said acceptance judgment, the reference values used for said acceptance judgment, or a value indicating the difference between the measured values used for said acceptance judgment and the reference values used for said acceptance judgment.

(5) Said system has the feature that it further includes a selection input section for inputting the selection of whether or not to output said acceptance judgment result in a visually verifiable manner, and said image output control section carries out said control when the selection has been input in said selection input section selecting the visually verifiable outputting of said acceptance judgment result.

(6) An image outputting system having a plurality of image outputting apparatuses that are installed at each separate location and that output to a recording medium color images based on image data, with said image outputting system having the feature that said plurality of image outputting apparatuses are connected via a network to a control server, and that said system comprises a reference value storing section that stores the reference values of color characteristics stipulated for reference colors for each type of apparatus of said plurality of image outputting apparatuses, a acceptance judgment section that receives the measured values of the color characteristics of reference colors outputted by and sent from the respective image outputting apparatus, with said measured values being measured using said measurement section and received along with the apparatus type of the respective image outputting apparatus, and makes acceptance judgment by comparing said received respective measured values with the reference values for the received apparatus type stored inside said reference value storing section, a judgment result storing section that stores the result of said acceptance judgment while establishing its correspondence with said received image outputting apparatus, and a control server that has a judgment information transmission section that receives from said image outputting apparatus an inquiry about the acceptance judgment result regarding the image outputting apparatus and transmits the judgment information indicating the acceptance judgment result for the image outputting apparatus of said inquiry, in said image outputting apparatus, not only color images are outputted based on image data to said recording medium but also the acceptance judgment result indicating said received judgment information is outputted in a visually verifiable manner.

(7) An image outputting system having a plurality of image outputting apparatuses that are installed at each separate location and that output color images based on image data to a plurality of types of recording media, with said image outputting system having the feature that said plurality of image outputting apparatuses are connected via a network to a control server and that said system comprises a reference value storing section that stores the reference values of color characteristics stipulated for each type of said recording media regarding the reference colors stipulated for each type of apparatus of said plurality of image outputting apparatuses, a acceptance judgment section that receives the measured values of the color characteristics of reference colors outputted by and sent from the respective image outputting apparatus, with said measured values being measured using said measurement section and received along with the apparatus type and the type of recording media of the respective image outputting apparatus, and makes acceptance judgment by comparing said received respective measured values with the reference values for the received apparatus type and for the received type of recording media stored inside said reference value storing section, a judgment result storing section that stores the result of said acceptance judgment while establishing its correspondence with said image outputting apparatus and said type of recording media, and a control server that has a judgment information transmission section that receives from said image outputting apparatus an inquiry about the acceptance judgment result for the type of recording media used for outputting by said image outputting apparatus and transmits the judgment information indicating the acceptance judgment result for the type of recording media of the image outputting apparatus of said inquiry, and in said image outputting apparatus, not only color images are outputted based on image data to said recording medium but also the acceptance judgment result indicating said received judgment information is outputted in a visually verifiable manner.

(8) Said judgment result storing section has the feature that it further stores the associated information related to said acceptance judgment decision result while establishing its correspondence, and said transmitted judgment information, further indicates the associated information, and in the image output control section said associated information is also outputted in addition to said acceptance judgment result in a visually verifiable manner.

(9) Said associated information has the feature that it is one or a plural number among the date and time at which acceptance judgment was made, the measured values used for said acceptance judgment, the reference values used for said acceptance judgment, or a value indicating the difference between the measured values used for said acceptance judgment and the reference values used for said acceptance judgment.

(10) Said system has the feature that it further includes a selection input section for inputting the selection of whether or not to output said acceptance judgment result in a visually verifiable manner, and said output is made when the selection has been input in said selection input section selecting the visually verifiable outputting of said acceptance judgment result.

(11) An image outputting method in an image outputting system having an image outputting apparatus that outputs to a recording medium color images based on image data, and with the feature that said method comprises a reference value storage step of storing the reference values of color characteristics stipulated for reference colors, a measurement step of measuring the values of color characteristics of reference colors outputted by said image outputting apparatus, a acceptance judgment step of making the acceptance judgment by comparing the measured values of said reference colors with said stored reference values, a step of storing said acceptance judgment result, and a step of controlling said image outputting apparatus so that not only color images are outputted based on image data to said recording medium but also said stored acceptance judgment result is outputted in a visually verifiable manner.

(12) An image outputting method in an image outputting system having an image outputting apparatus that outputs to a plurality of types of recording media color images based on image data, and with the feature that said method comprises a step of storing the reference values of color characteristics stipulated regarding the reference colors for each type of said recording media, a step of measuring the values of color characteristics of reference colors outputted by said image outputting apparatus to each type of said recording media, a step of making acceptance judgment by comparing the measured values of said reference colors for each type of said recording media with said stored reference values for each type of said recording media, a step of storing the results of said acceptance judgment while establishing correspondence between said acceptance judgment results and the types of said recording media, and a step of controlling said image outputting apparatus so that not only color images are outputted based on image data to any one type among a pluralities of types of said recording media but also said stored acceptance judgment result for the type of said recording media used is outputted in a visually verifiable manner.

(13) An image outputting method in an image outputting system having a plurality of image outputting apparatuses that are installed at each separate location and that output to a recording medium color images based on image data, with said image outputting method having the feature that, in a control server which is connected to said plurality of image outputting apparatuses via a network, said method comprises a step of storing the reference values of color characteristics stipulated for reference colors for each type of apparatus of said plurality of image outputting apparatuses, a step of receiving the measured values of the color characteristics of reference colors outputted by and sent from the respective image outputting apparatus and of receiving also the apparatus type of the respective image outputting apparatus, and a step of making acceptance judgment by comparing said received respective measured values with said stored reference values for the received apparatus type, a step of storing the result of said acceptance judgment while establishing its correspondence with said received image outputting apparatus, and step of receiving from said image outputting apparatus an inquiry about the acceptance judgment result regarding the image outputting apparatus, and a step of transmitting the judgment information indicating the acceptance judgment result for the image outputting apparatus of said inquiry, and with the further feature that, in said image outputting apparatus, a step of outputting not only color images based on image data to said recording medium but also of outputting the acceptance judgment result indicated by said received judgment information in a visually verifiable manner.

(14) An image outputting method in an image outputting system having a plurality of image outputting apparatuses that are installed at each separate location and that output color images based on image data to a plurality of types of recording media, with said image outputting method having the feature that, in a control server connected to said plurality of image outputting apparatuses via a network, said method comprises a step for storing the reference values of color characteristics stipulated for each type of said recording media regarding the reference colors stipulated for each type of apparatus of said plurality of image outputting apparatuses, a step for receiving the values measured by said measurement section of the color characteristics of reference colors outputted by and sent from the respective image outputting apparatus, along with the apparatus type and the type of recording media of the respective image outputting apparatus used for that measurement, and a step of making acceptance judgment by comparing said received respective measured values with said stored reference values for said stored received apparatus type and for said received type of recording media, a step of storing the result of said acceptance judgment while establishing its correspondence with said image outputting apparatus and said type of recording media, a step of receiving from said image outputting apparatus an inquiry about the acceptance judgment result for the type of recording media used for outputting by said image outputting apparatus, and a step of transmitting the judgment information indicating the acceptance judgment result for the type of recording media of the image outputting apparatus of said inquiry, and with the further feature that, in said image outputting apparatus, a step of outputting not only color images based on image data to said recording medium but also of outputting the acceptance judgment result indicated by said received judgment information in a visually verifiable manner.

According to the image outputting system of structure (1) above, it is possible to judge pass or fail of the colors outputted by the image outputting apparatus, and to output that acceptance judgment result on to the recording medium along with the image in a visually verifiable manner. Because of this, it is possible to judge by looking at the printed material whether color management has been made of the corresponding image outputting apparatus.

According to the image outputting system of structure (2) above, it is possible to judge for each recording paper the pass or fail of the colors outputted by the image outputting apparatus, and to output for each recording paper that acceptance judgment result on to the recording medium along with the image in a visually verifiable manner. Because of this, it is possible to judge for each recording paper by looking at the printed material whether color management has been made of the corresponding image outputting apparatus.

According to the image outputting system of structure (3) above, it is possible to output in a visually verifiable manner not only the acceptance judgment result but also the associated information related to the acceptance judgment result.

According to the image outputting system of structure (4) above, outputting the date and time at which the acceptance judgment was made in a visually verifiable manner provides a guideline for deciding when to carry out the operations for color manual. Further, it is possible to grasp quantitatively the level of output colors of the image outputting apparatus by outputting in a visually verifiable manner the measured values used for acceptance judgment, the reference values used for acceptance judgment, or the difference between the measured values used for acceptance judgment and the reference values used for acceptance judgment.

According to the image outputting system of structure (5) above, it is possible to select whether or not to output in a visually verifiable manner the acceptance judgment result.

According to the image outputting system of structure (6) above, by making acceptance judgment of the colors outputted by the image outputting apparatus at each location and by providing that acceptance judgment result using a control server, it is possible to output in a visually verifiable manner the acceptance judgment result along with the image on to the record medium in the image outputting apparatus. Because of this, it is possible to carry out unified management of output colors of the image outputting apparatuses installed at each location, and furthermore, to judge whether or not color management has been made of the image outputting apparatus by looking at each output material.

According to the image outputting system of structure (7) above, by making acceptance judgment using a control server, for each recording paper that is output, of the colors outputted by the image outputting apparatus at each location and by providing that acceptance judgment result for each recording paper that is outputted, it is possible to output, for each recording paper that is outputted, in a visually verifiable manner the acceptance judgment result along with the image on to the record medium in the image outputting apparatus. Because of this, it is possible to carry out unified management of output colors, for each recording paper that is outputted, of the image outputting apparatuses installed at each location, and furthermore, to judge whether or not color management has been made of the image outputting apparatus by looking at each output material.

According to the image outputting system of structure (9) above, it is possible to output in a visually verifiable manner not only the acceptance judgment result but also the associated information related to the acceptance judgment result.

According to the image outputting system of structure (9) above, outputting the date and time at which the acceptance judgment was made in a visually verifiable manner provides a guideline for deciding when to carry out the operations for color manual. Further, it is possible to grasp quantitatively the level of output colors of the image outputting apparatus by outputting in a visually verifiable manner the measured values used for acceptance judgment, the reference values used for acceptance judgment, or the difference between the measured values used for acceptance judgment and the reference values used for acceptance judgment.

According to the image outputting system of structure (10) above, it is possible to select whether or not to output in a visually verifiable manner the acceptance judgment result.

According to the image outputting method of structure (11) above, it is possible to judge pass or fail of the colors outputted by the image outputting apparatus, and to output that acceptance judgment result on to the recording medium along with the image in a visually verifiable manner. Because of this, it is possible to judge by looking at the printed material whether color management has been made of the corresponding image outputting apparatus.

According to the image outputting method of structure (12) above, it is possible to judge pass or fail of the colors outputted by the image outputting apparatus for each recording paper that is outputted, and to output that acceptance judgment result for each recording paper that is outputted, on to the recording medium along with the image in a visually verifiable manner. Because of this, it is possible to judge, for each recording paper that is outputted, by looking at the printed material whether color management has been made of the corresponding image outputting apparatus.

According to the image outputting method of structure (13) above, by making acceptance judgment of the colors output by the image outputting apparatus at each location and by providing that acceptance judgment result using a control server, it is possible to output in a visually verifiable manner the acceptance judgment result along with the image on to the record medium in the image outputting apparatus. Because of this, it is possible to carry out unified management of output colors of the image outputting apparatuses installed at each location, and furthermore, to judge whether or not color management has been made of the image outputting apparatus by looking at each output material.

According to the image outputting method of structure (14) above, by making acceptance judgment using a control server, for each recording paper that is outputted, of the colors output by the image outputting apparatus at each location and by providing that acceptance judgment result for each recording paper that is outputted, it is possible to output, for each recording paper that is outputted, in a visually verifiable manner the acceptance judgment result along with the image on to the record medium in the image outputting apparatus. Because of this, it is possible to carry out unified management of output colors, for each recording paper that is outputted, of the image outputting apparatuses installed at each location, and furthermore, to judge whether or not color management has been made of the image outputting apparatus by looking at each output material.

### EMBODIMENTS OF THE INVENTION

Some preferred embodiments of the image outputting system and the image outputting method according to the present invention are described in concrete terms in the following while referring to the figures.

A feature of the present invention is outputting in a visually verifiable manner the result of judgment for each output color of the outputting apparatus, along with the output of the image data, at the time of outputting from the outputting apparatus an output material, for example, a color proof as a trial print of the image data during the interval between receiving the print order and completing the printing job.

### The First Embodiment

System Configuration:

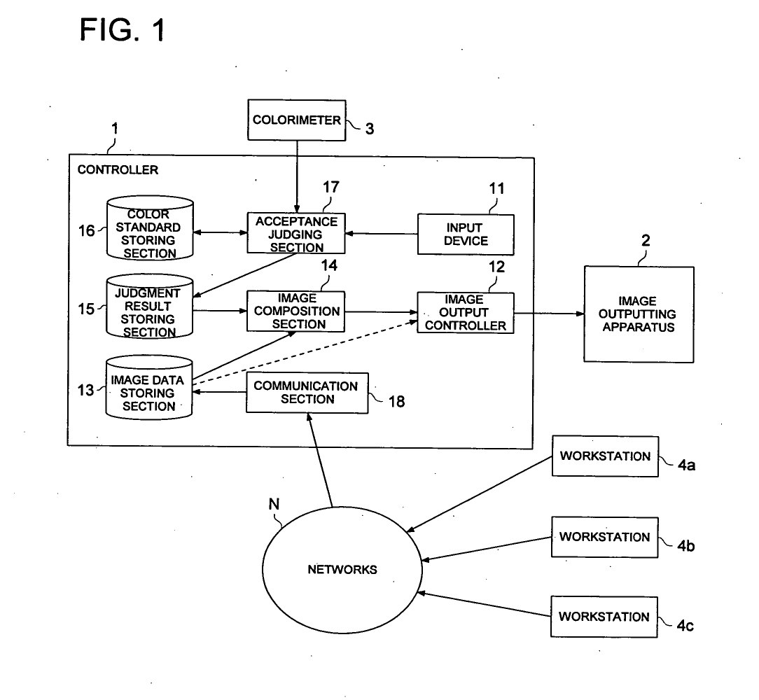

To begin with, the control configuration of the image outputting system according to the present invention is described here using FIG. 1. FIG. 1 is a functional block diagram showing the system configuration of this image outputting system. As is shown in FIG. 1, this image outputting system is configured to comprise work terminals (work terminals) 4 (the three units 4a, 4b, and 4c in FIG. 1) that prepare the image data for outputting in the image outputting apparatus 2 and transmit it to the controller 1, the image outputting apparatus 2 that outputs images on to recording paper (recording medium), the controller 1 that carries out image outputting control of the image outputting apparatus 2 so that images are outputted based on the image data transmitted from the work terminals 4 via the network N, and the calorimeters 3 as the measurement section for measuring the color tone or color densities of the color patch P that is outputted from the image outputting apparatus 2.

The network N interconnects the computer system, the terminals, and the data communication equipment, wherein the connections can be either wired connections such as using lease lines or public switch telephone lines, or can be wireless connections such as those using communication satellites. In addition, this network can also be an Internet based network.

The image outputting apparatus 2 is configured to include an image outputting section in which recording paper, not shown in the figure, is taken in, and the recording paper is outputted after images are formed on it, an operating panel (not shown in the figure) for inputting various types of operations, and a control section (not shown in the figure) for controlling the entire image outputting apparatus 2, and this image outputting apparatus 2 outputs the images upon receiving the image data transmitted from the controller 1.

The work station (work terminal) 4 (4a-4c) are PCs (Personal Computers) which are provided with application software, have the functions of preparing the image data by executing the application software, displaying the printing screen for carrying out the image output, and transmitting to the controller 1 connected to the image outputting apparatus 2 the header section of the image data to which are added the specified image outputting apparatus, the specified type of recording paper used for the output, and the size of the recording paper, etc.

The controller 1 is a computer provided with an input section 11 such as keyboard, mouse, etc., and a display section (not shown in the figure) such as a CRT (Cathode Ray Tube) or an LCD (Liquid Crystal Display). Further, the controller 1 is provided with a color standard storing section 16 (reference value storing section) that stores the color references as the reference values stipulated for the reference colors, a acceptance judgment section (acceptance judging section) 17 that receives the values measured for the color patch P measured by the calorimeter 3 and compares it with the color reference stored in the color standard storing section 16, the communication section 18 that receives the image data transmitted from the work terminals 4 via the network N, and the image data storing section 13 that stores the received image data. In addition, the controller 1 is provided with the judgment result storing section 15 that stores the acceptance judgment result for the output color, the image composition section 14 that, for example, at the time of outputting the image data transmitted from the work terminal 4 to the image outputting apparatus 2, refers to the judgment result storing section 15 and synthesizes data indicating the acceptance judgment of the output color with the image data, and an image outputting control section 12 that carries out control, in the case when the acceptance judgment result is to be outputted, so as to carry out image output based on the synthesized image data by transmitting the synthesized image data to the image outputting apparatus 2, and in the case when the acceptance judgment result is not to be outputted, so as to carry out image output based on the image data received from the work terminals 4.

By configuring in the above manner, it is possible to output in a visually verifiable manner the acceptance judgment result judged for the output color of the image outputting apparatus 2.

Output color acceptance judgment procedure and acceptance judgment result output procedure:

Next, the acceptance judgment procedure for the output color carried out in this image outputting system is explained here. In the present example, the acceptance judgment of the output color is carried out using the reference color output from the image outputting apparatus.

To begin with, the measured of the values of color characteristics such as the color tone and color density of the reference color output from the image outputting apparatus 2 is explained here. However, in the present preferred embodiment, the color patch P having the plurality of colors as the reference colors is outputted, and the density of each color in the color patch, in specific terms, Dc (cyan density), Dm (magenta density), Dy (yellow density), and Dv (visual density), and the values in the system of color representation, specifically, the L*a*b* value in the CIE L*a*b* system of color representation are measured, and are used for the judgment described later. It goes without saying that as long as they represent the color tone or the color density it is possible to use the RGB densities or the tristimulus values of X, Y, and Z in the XYZ system of color representation as the values in the system of color representation.

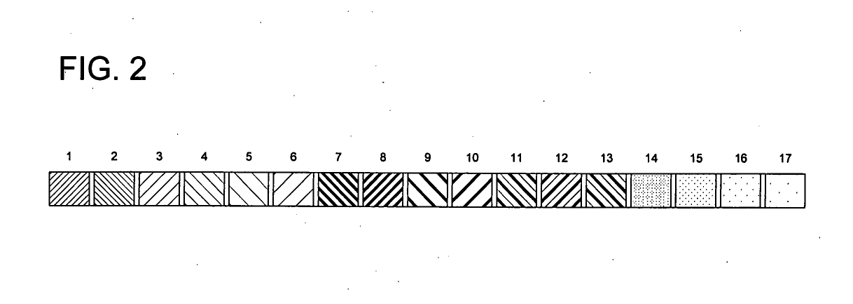

Firstly, an example of configuration of the color patch P described above is explained below. In the color patch P, as is shown in FIG. 2, the 17 colors of C100%, M100%, Y100%, K100%, CMY100%, MY100%, CY100%, CM100%, W (white background), C50%, M50%, Y50%, K50%, CMY10%, CMY20%, CMY40%, and CMY70% have been arranged in a series in the order of the numbers assigned from the left for the sake of explanation. Further, at the time of measurement using the measurement screen 21 to be described later, the measurement will be made in the order of the numbers assigned here. In the present example, although the color patch P is shown to have 17 colors it is sufficient if at least onebcolor is present as the reference color for use in the acceptance judgment. In addition, although in the present example the values of the densities and the values in the system of color representation are both being measured as the values of the color characteristics, it is possible to use either the densities or the values in the system of color representation.

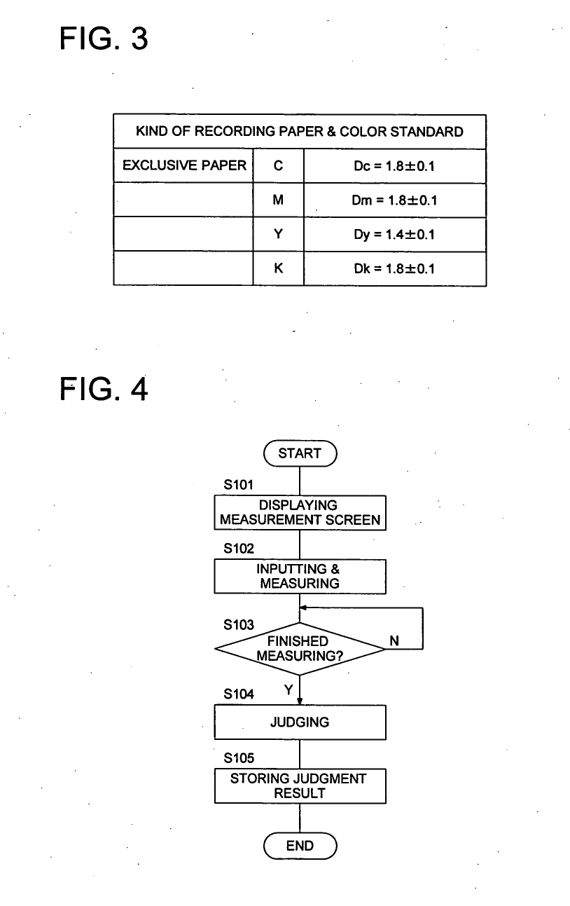

Further, the color reference stored in the color standard storing section 16 is described here. The color reference is indicated by a specific range of values of color characteristics such as the density or the color difference with the color reference, for example, as is shown in FIG. 3. In FIG. 3, the values Dc, Dm, Dy, and Dv have been stipulated as the color reference values respectively for C100%, M100%, Y100%, and K100% for each type of recording paper (only special paper is shown in FIG. 3). In the present example, although the color references were taken as 100% each of CMYK, that is, as the solid densities of CMYK, it is also possible to use either the densities or the color difference with the L*a*b* value in the L*a*b* system of color representation or their combination for intermediate shades.

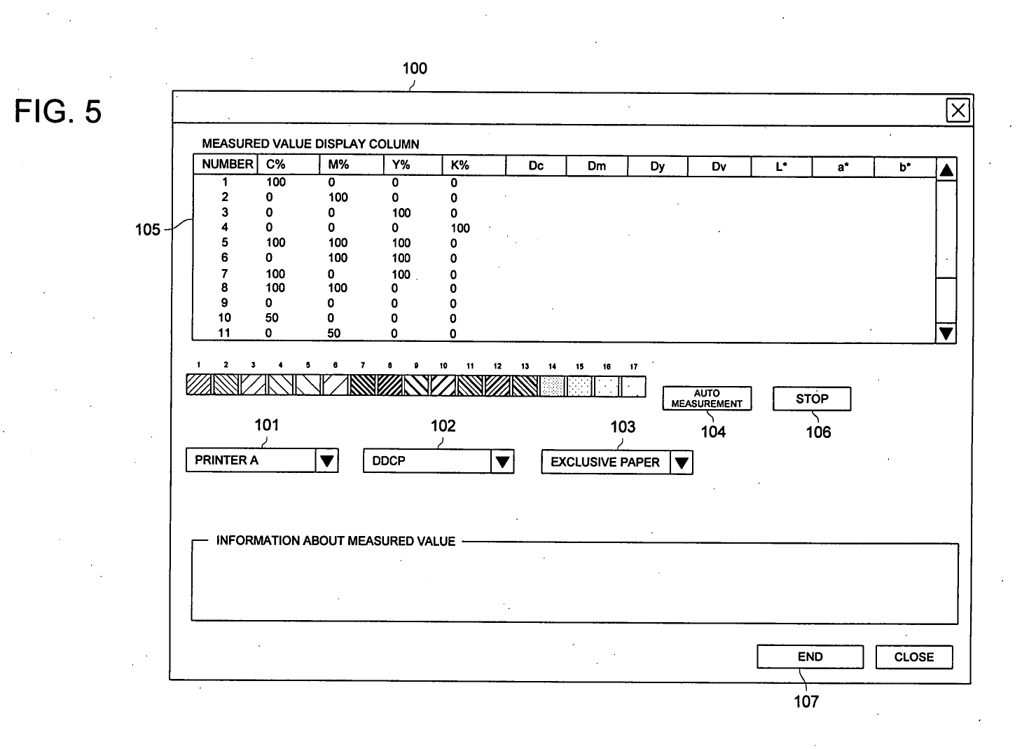

Next, an example of a procedure of carrying out acceptance judgment of output colors using the color patch P is explained here. FIG. 4 is a flowchart showing the procedure of making the acceptance judgment of output colors according to the present invention. The operator operates the input section 11 such as the keyboard or mouse of the controller 1, and displays in the display section the measurement screen 100 shown as an example in FIG. 5 (Step S101; “Step 101” is abbreviated as “S101” in the following, the same notation being used for other steps also). Next, the operator operates the input section 11 and inputs the apparatus name denoting the image outputting apparatus 2 in the input field 101, the apparatus type in the input field 102 indicating the method or performance capabilities of the image outputting apparatus 2 such as the “apparatus type” or the “apparatus model”, the type of recording paper used for outputting in the input field 103 by selecting the items to be specified from the respective pull-down menus (the pull-down menus display the contents registered beforehand in a selectable manner), and when the operator subsequently clicks the “Measure” key 104, the apparatus goes into the measured value awaiting state. As the operator measures the color patch P in the order of the numbers using the calorimeter 3, the measured values are displayed in the measured value display field 105 in the order of the number in the color patch P (S102). The “Abort” key 106 is used for terminating the measurements in the middle.

When the above measurement is completed and the operator clicks the end key 107 (S103, Y), the acceptance judgment section 17 acquires the measurement result and the type of recording paper used, and compares the measurement result with the color reference value in the color standard storing section 16 corresponding to the acquired type of recording paper, and if the measured value of each color satisfies the density of the color standard, the output color is judged to have passed, and to have failed when there is even one color that does not satisfy the density of the color standard (S104). Next, that result of judgment is stored in the judgment result storing section 15 while establishing the correspondence between the judgment result and the type of recording paper (S105).

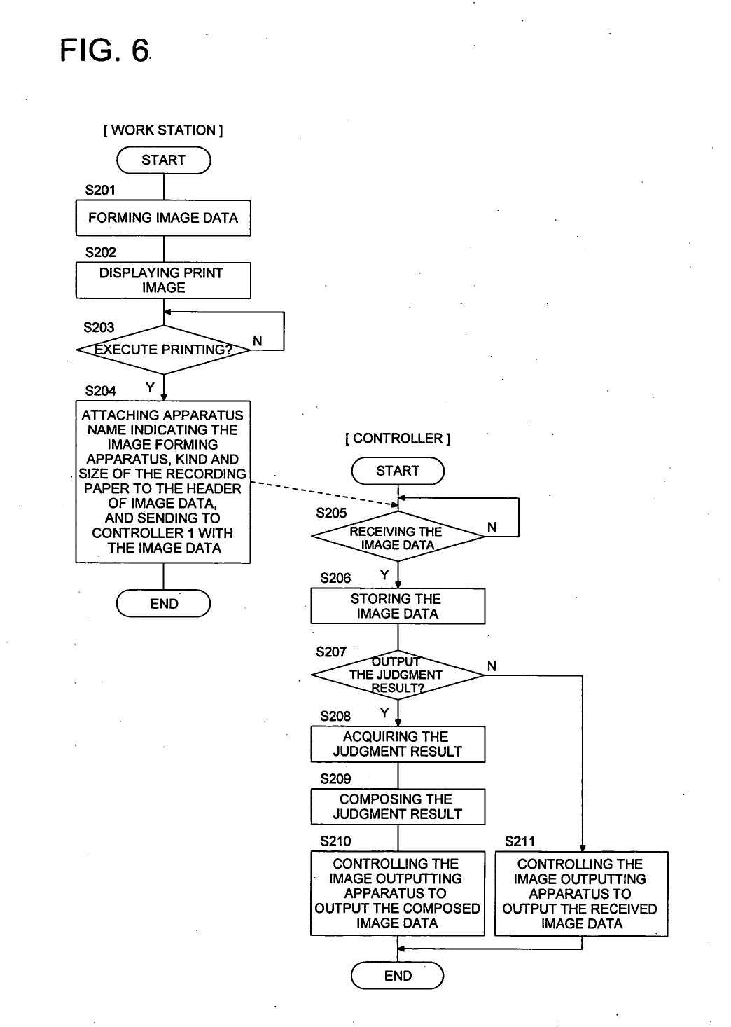

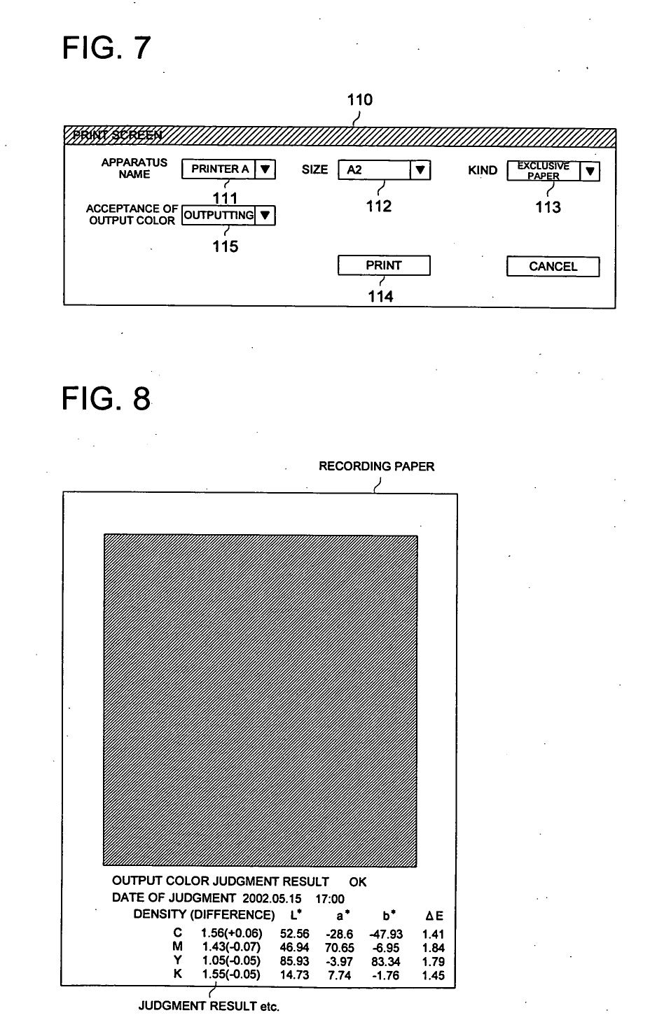

Next, the outline of the image outputting procedure is explained here referring to the flow chart of FIG. 6. The operator executes the application software in the work terminal 4 and prepares the image data (S201), next operates the mouse, etc., and displays the print screen 110 shown as an example in FIG. 7 (S202). Next, the operator operates the mouse, etc., and inputs the apparatus name denoting the image outputting apparatus 2 in the input field 111, the size of the recording paper in the input field 112, the type of recording paper used for outputting in the input field 113 by selecting the items to be specified from the respective pull-down menus (the pull-down menus display the contents registered beforehand in a selectable manner), and when the operator subsequently selects whether or not to output the acceptance judgment result of output colors using the pull-down menu and clicks the “Print” key 114 (S203), the apparatus name indicating the image output apparatus 2 which is the destination of the output, the type of recording paper, the size of recording paper, and whether or not to output the acceptance judgment result of the output colors is added to the header part, etc. of the image data and transmitted along with the image data to the controller 1 connected to the image outputting apparatus 2 which is the output destination (S204). The input field 115 of the printing screen 110 constitutes the selection input section of the present invention.

The controller 1 receives the transmitted image data (S205, Y), and stores it in the image data storing section 13 (S206). When the acceptance judgment result of the output colors is to be outputted (S207, Y), the image synthesizing section 14 refers to the header part of the image data and judges the type of recording paper, and then refers to the judgment result storing section 15 and obtains the acceptance judgment result for that type of recording paper (S208). Next, it synthesizes the image data so that the obtained acceptance judgment result is outputted in a visibly verifiable manner at a specific location at the time of making the image output of the image data (S209). Next, the synthesized image is sent to the image outputting control section 12, and the image outputting control section 12 controls the image outputting apparatus 2 so as to output the synthesized image data on a recording paper of the specified type of recording paper (S210). The image outputting apparatus 2 outputs in a visibly verifiable manner the image together with which the acceptance judgment result has been synthesized. Further, when the acceptance judgment result of the output colors is not to be outputted (S207, N), the image outputting control section 12 controls the image outputting apparatus 2 so as to output the received image data on a recording paper of the specified type of recording paper (S211).

Further, in the above explanation, although the acceptance judgment result was made in order to give the output in a visibly verifiable manner, it is also possible to output, in addition to the acceptance judgment result, the date and time at which the judgment was made, the measured values used during the judgment, or the difference between the measured values and the color reference values. In that case, the judgment result storing section 15 can obtain, from the acceptance judgment section 17, the date and time at which the judgment was made, the measured values used during the judgment, or the difference between the measured values and the color reference values, and can store them while establishing their correspondence with the acceptance judgment result. However, the difference with the color reference will have to be calculated in the acceptance judgment section 17. In addition, it is also possible to make the output while adding the color reference values, and in that case, while the image synthesizing section 14 obtains the color reference values by referring to the color standard storing section 16 in addition to the judgment result storing section 15, it is sufficient to store this in the judgment result storing section 15 while establishing their correspondence with the acceptance judgment result. Further, the measured values and the color reference values can be expressed by the densities or by the values in the system of color representation, and the difference with the color reference values can be expressed by the density difference or the color difference. Regarding this, an example of outputting the acceptance judgment result, etc. in a visibly verifiable manner is shown in FIG. 8.

Further, it is also possible to configure an image outputting system according to the present invention using an image outputting apparatus provided with the different sections of the controller 1 described above.

### The Second Embodiment

Next, a second preferred embodiment of the present invention is described here. However, in the following, detailed descriptions have been omitted for the parts of the configuration that are effectively identical to those of the first preferred embodiment, and mainly the points of difference between the first and the second preferred embodiment are described below.

System Configuration:

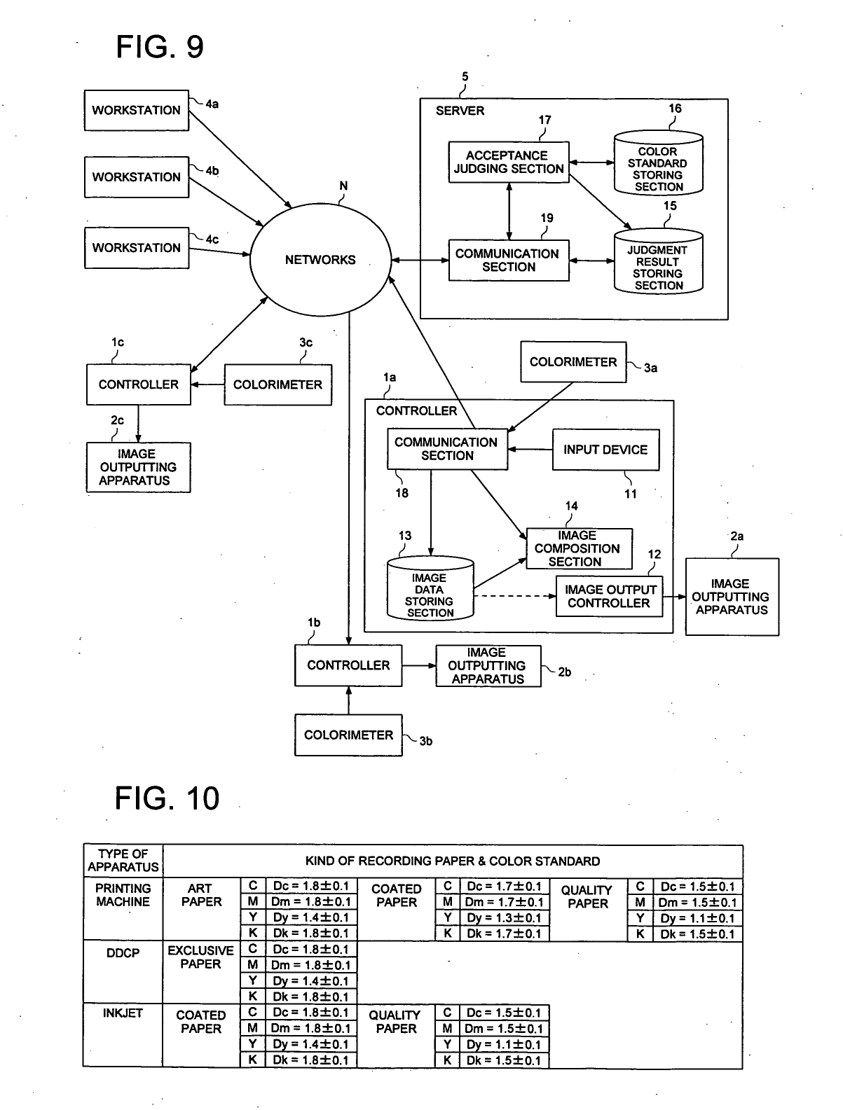

To begin with, the control configuration of the image outputting system according to the second preferred embodiment of the present invention is described here using FIG. 9. FIG. 9 is a functional block diagram showing the system configuration of the image outputting system in the second preferred embodiment. As is shown in FIG. 9, this image outputting system is configured to the comprise controller 1, the image outputting apparatus 2, and the calorimeter 3 installed at each of the plurality of distant locations (these are the sets of three units each of 1a, 1b, 1c, 2a, 2b, 2c, and 3a, 3b, 3c in FIG. 9), each controller 1 being connected to the network, and the system further comprises a server (control server) 5 which carries out the acceptance judgment of the output colors outputted from each image outputting apparatus 2, and which provides the acceptance judgment result as the judgment information.

The server (control server) 5 is a computer, and is provided with an input section such as a keyboard, mouse, etc., a display section such as a CRT or an LCD, and the main unit of the apparatus including the server. In addition, the control server 5 comprises the color standard storing section 16 that stores the color reference values, the acceptance judgment section 17 that receives, using the communication section 19 via the network N, the measured values of the color patch P measured using the calorimeter 3, compares them with the color reference values stored in the color standard storing section 16, and makes the acceptance judgment of the output color outputted from the image outputting apparatus 2, and the judgment result storing section 15 that stores that acceptance judgment result. In addition, the communication section 19 has the function of the judgment information transmission section that transmits the judgment information in answer to the inquiry for the acceptance judgment result from the controller 1.

The work station (work terminal) 4 is provided with the functions of displaying the printing screen for carrying out the image output and for selecting the desired image outputting apparatus, and, in a manner similar to that in the first preferred embodiment, for specifying the material of the recording paper used for the output and the size of the recording paper, and for transmitting to the controller 1 connected to the image outputting apparatus 2 while adding them to the header section of the image data, and transmitting them along with the image data to the controller 1 connected to the desired image outputting apparatus.

The communication section 18 of the controller 1 has the function of a measured value transmission section that transmits the measured values of the color patch P measured by the calorimeter 3, and the function of a judgment information receiving section that sends an inquiry for the acceptance judgment result to the control server 5 and receives from the control server 5 the judgment information indicating the acceptance judgment result.

By configuring in the above manner, it is possible to judge the output colors of a plurality of image outputting apparatuses connected to the network N, to carry out unified management of the acceptance judgment result, and to output in a visually verifiable manner the acceptance judgment result judged for the output colors of each image outputting apparatus.

Output color acceptance judgment procedure and acceptance judgment result output procedure:

Further, the color reference values stored in the color standard storing section 16 are described here. The color reference values in the present preferred embodiment are indicated for each apparatus type and for each type of recording paper by a specific range of values of color characteristics such as the density or the color difference with the color reference, for example, as is shown in FIG. 10. In FIG. 10, the possible target apparatus types are taken as printing machines, DDCP, and inkjet printers, and for each of these apparatus types and for each type of recording paper, the values Dc, Dm, Dy, and Dv have been stipulated as the color reference values respectively for C100%, M100%,. Y10%, and K100%.

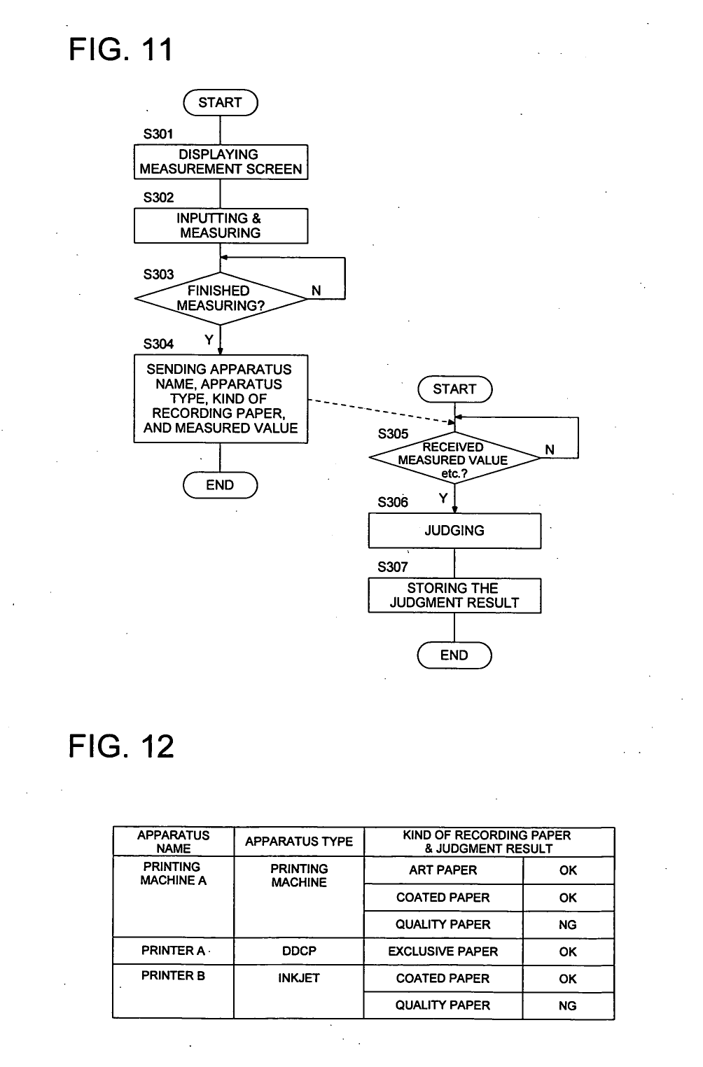

Next, an example of a procedure of carrying out acceptance judgment of output colors using the color patch P is explained here. FIG. 11 is a flowchart showing the procedure of making the acceptance judgment of output colors. The operator operates the input section 11 such as the keyboard or mouse of the controller 1, and displays in the display section the measurement screen 100 shown as an example in FIG. 5 (Step S301). Next, the operator operates the input section 11 and inputs the apparatus name denoting the image outputting apparatus 2 in the input field 101, the apparatus type of the image outputting apparatus 2 in the input field 102, the type of recording paper used for outputting in the input field 103 by selecting the items to be specified from the respective pull-down menus (the pull-down menus display the contents registered beforehand in a selectable manner), and when the operator subsequently clicks the “Measure” key 104, the apparatus goes into the measured value awaiting state. As the operator measures the color patch P in the order of the numbers using the colorimeter 3, the measured values are displayed in the measured value display field 105 in the order of the number in the color patch P (S302). The “Abort” key 106 is used for ending the measurements in the middle.

When the above measurement is completed and the operator clicks the end key 107 (S303, Y), the apparatus name, the apparatus type, the type of recording paper, and the measured values are transmitted to the control server 5 via the network N (S304). These are received by the control server 5 (S305, Y), and the acceptance judgment section 17 compares the measurement result with the color reference value in the color standard storing section 16 corresponding to the received apparatus type and type of recording paper, and if the measured value of each color satisfies the density of the color standard, the output color is judged to have passed, and to have failed when there is even one color that does not satisfy the density of the color standard (S306). Next, that result of judgment is stored, with the configuration shown in FIG. 12 as an example, in the judgment result storing section 15 while establishing the correspondences of the judgment result to the apparatus name, the apparatus type, and to the type of recording paper (S307).

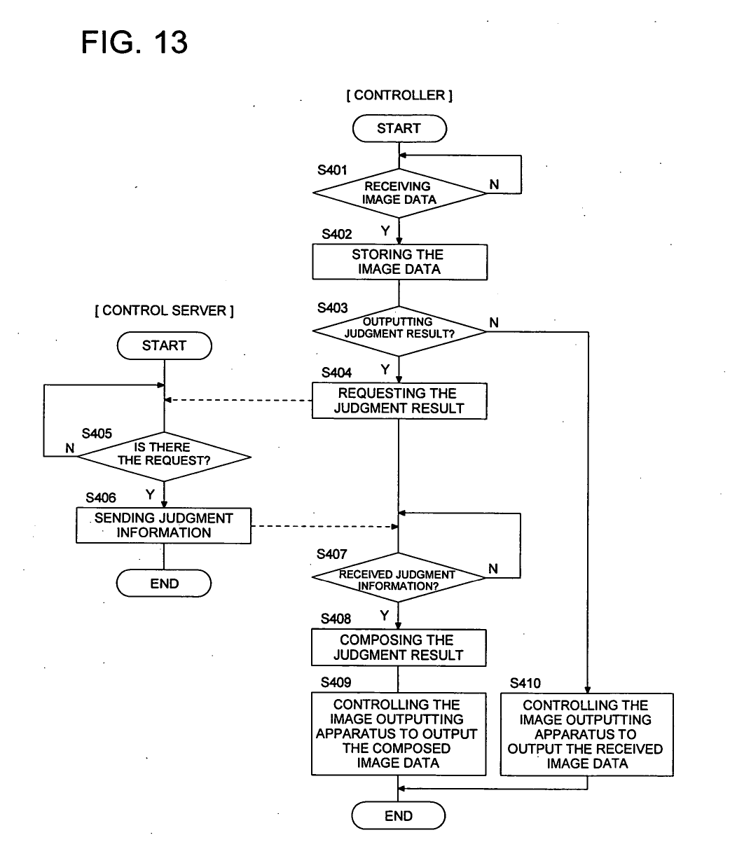

Next, the outline of the image outputting procedure is explained here referring to the flow chart of FIG. 13. The controller 1, similar to that in the first preferred embodiment, receives the image data (S401, Y) transmitted after adding to its header part the apparatus name indicating the image output apparatus 2 that is the destination of the output, the type of recording paper, the size of recording paper, and whether or not to output the acceptance judgment result of the output colors, and stores it in the image data storing section 13 (S402). When the acceptance judgment result of the output colors is to be outputted (S403, Y), the image synthesizing section 14 refers to the header part of the image data, judges the type of recording paper, and sends an inquiry to the control server via the network N (S404) for the acceptance judgment result for the type of recording paper and for the apparatus name of the image outputting apparatus that has been connected. The control server 5 receives this inquiry (S405, Y), searches the judgment result storing section 15 using the received apparatus name and type of recording paper, and transmits the corresponding acceptance judgment result as the judgment information to the controller 1 via the network N (S406). Next, the controller 1 receives the judgment information (S407, Y), and the image synthesizing section 14 synthesizes the image data so that the obtained acceptance judgment result is outputted in a visibly verifiable manner at a specific location at the time of making the image output of the image data (S408). Next, the synthesized image is sent to the image outputting control section 12 and the image outputting control section 12 controls the image outputting apparatus 2 so as to output the synthesized image data in a recording paper of the specified type of recording paper (S409). The image outputting apparatus 2 outputs in a visibly verifiable manner the image with which the acceptance judgment result has been synthesized. Further, when the acceptance judgment result of the output colors is not to be outputted (S403, N), the image outputting control section 12 controls the image outputting apparatus 2 so as to output the synthesized image data in a recording paper of the specified type of recording paper (S410).

Further, when outputting, in addition to the acceptance judgment result, the date and time at which the judgment was made, the measured values used during the judgment, or the difference between the measured values and the color reference values, it is sufficient to transmit these as the judgment information along with the acceptance judgment result. Further, even when the color reference values are outputted in addition to these, it is sufficient to transmit the color reference values as the judgment information along with the acceptance judgment result.

1. An image outputting system comprising:
an image outputting apparatus for outputting color images onto a recording medium based on image data;
a reference value storing section for storing reference values of color characteristics stipulated for reference colors;
a measurement section for measuring values of color characteristics of reference colors outputted by the image outputting apparatus;
an acceptance judgment section for making judgment of acceptance by comparing measured values of the reference colors measured by the measurement section with the reference values stored in the reference value storing section;
a judgment result storing section for storing a result of the judgment of acceptance; and
an image output controller for controlling the image outputting apparatus so that the apparatus outputs onto the recording medium the color images based on image data, and also outputs the result of the judgment of acceptance in a visually verifiable manner.

2. The image outputting system of claim 1, wherein the image outputting apparatus outputs color images onto a plurality of types of recording media based on image data,
the reference value storing section stores the reference values of color characteristics stipulated regarding the reference colors for each type of the recording media,
the measurement section measures the values of color characteristics of reference colors outputted by the image outputting apparatus onto the each type of the recording media,
the acceptance judgment section makes the judgment of acceptance by comparing the measured values of the reference colors for each type of the recording media measured by the measurement section with the reference values for each type of the recording media stored in the reference value storing section,
the judgment result storing section stores results of the judgment of acceptance while relating the results of the judgment of acceptance with the each type of the recording media, and
the image output controller controls the image outputting apparatus so that the apparatus outputs onto any one type of the recording media among the pluralities of types of recording media the color images based on the image data, and also outputs the result of the judgment of acceptance for the each type of the recording media used in a visually verifiable manner.

3. The image outputting system of claim 1, wherein the judgment result storing section stores associated information to the result of the judgment while relating the associated information with the result of the judgment of acceptance,
and the image output controller controls the image outputting apparatus to output the associated information in a visually verifiable manner, in addition to outputting the result of the judgment of acceptance.

4. The image outputting system of claim 3, wherein the associated information comprises at least one of a date and time when the judgment of acceptance was made, the measured values used for the judgment, the reference values used for the judgment, and values indicating differences between the measured values used for the judgment and the reference values used for the judgment.

5. The image outputting system of claim 1, further comprising a selection input section for inputting a selection of whether or not to output the judgment result in a visually verifiable manner, wherein when the selection to output the judgment result has been inputted in the selection input section, the image output controller controls the image outputting apparatus so that the apparatus outputs onto the recording medium the color images based on the image data, and also outputs the result of the judgment of acceptance in a visually verifiable manner.

6. An image outputting system comprising:
a plurality of image outputting apparatuses for outputting color images onto a recording medium based on image data, each of the plurality of image outputting apparatuses being installed at each location; and
a control server connected through network to the plurality of image outputting apparatuses, the control server comprising:
a reference value storing section for storing reference values of color characteristics stipulated for reference colors for each type of apparatus of the plurality of image outputting apparatuses;
an acceptance judgment section that receives measured values of the color characteristics of reference colors outputted by and sent from each apparatus of the plurality of image outputting apparatuses, and carries out a judgment of acceptance by comparing the respective measured values received with the reference values for the each type of apparatus stored in the reference value storing section;
a judgment result storing section for storing results of the acceptance judgment while relating the results with the each apparatus;
a judgment information transmission section that receives, from each side of the plurality of image outputting apparatuses, an inquiry about the acceptance judgment result regarding the each apparatus, and transmits the judgment information indicating the result of acceptance judgment for the each apparatus;
wherein, the each apparatus of the plurality of image outputting apparatuses, outputs onto the recording medium the color images based on the mage data, and also outputs the result of the acceptance judgment transmitted, in a visually verifiable manner.

7. The image outputting system of claim 6, wherein:
the plurality of image outputting apparatuses outputs color images onto plural types of recording media based on the image data; and
the reference value storing section stores reference values of color characteristics stipulated for each type of recording media regarding the reference colors of the each type of apparatus,
the acceptance judgment section receives information of the measured values of the color characteristics of reference colors outputted on each type of recording media, the type of the apparatus, and the type of the media used for outputting the reference colors, and carries out the judgment of acceptance by comparing the respective measured values received with the reference values for the each type of the apparatus and for the each type of recording media stored in the reference value storing section,
the judgment result storing section stores the results of the acceptance judgment while relating the results with the each apparatus and the each type of recording media,
the judgment information transmission section receives, from each side of the plurality of image outputting apparatuses, an inquiry about the acceptance judgment result regarding the type of the recording media to be used for outputting by the each apparatus, and transmits the judgment information indicating the acceptance judgment result for the each type of the recording media and the each apparatus.
wherein, the each apparatus of the plurality of image outputting apparatuses, outputs onto the recording medium the color images based on the image data, and also outputs the result of the judgment of acceptance transmitted in a visually verifiable manner.

8. The image outputting system of claim 6, wherein the judgment result storing section stores associated information to the result of the judgment while relating the associated information with the result of the judgment of acceptance,
the judgment information to be transmitted includes the associated information, and
the image output controller controls the each apparatus of the plurality of image outputting apparatuses to output the associated information in a visually verifiable manner, in addition to outputting the result of the judgment of acceptance.

9. The image outputting system of claim 8, wherein the associated information comprises at least one of a date and time when the judgment of acceptance was made, the measured values used for the judgment, the reference values used for the judgment, and values indicating a difference between the measured values used for the judgment and the reference values used for the judgment.

10. The image outputting system of claim 6, further comprising a selection input section for inputting a selection of whether or not to output the result of the judgment in a visually verifiable manner, wherein when the selection to output the judgment result has been inputted in the selection input section, the each apparatus of the plurality of image outputting apparatuses outputs onto the recording medium the color images based on image data, and also outputs the result of the judgment of acceptance transmitted in a visually verifiable manner.

11. An image outputting method for outputting images with an image outputting apparatus which outputs color images onto a recording medium based on image data, the image outputting method comprising:
storing reference values of color characteristics stipulated for reference colors;
measuring values of color characteristics of reference colors outputted by the image outputting apparatus;
making judgment of acceptance by comparing measured values of the reference colors with the reference values stored;
storing a result of the judgment of acceptance; and
controlling the image outputting apparatus so that the apparatus outputs onto the recording medium the color images based on the image data, and also outputs a result of the judgment of acceptance in a visually verifiable manner.

12. The image outputting method of claim 11, wherein the image outputting apparatus outputs color images onto a plurality of types of recording media based on image data, the image outputting method further comprising:
storing the reference values of color characteristics stipulated regarding the reference colors for each type of plurality of types of recording media,
measuring the values of color characteristics of reference colors outputted by the image outputting apparatus onto the each type of the recording media,
making judgment of acceptance, by comparing measured values of the reference colors for the each type of the recording media measured with the reference values for the each type of the recording media stored,
storing the results of the judgment of acceptance while relating the results of the judgment of acceptance with the each type of the recording media, and
controlling the image outputting apparatus so that the apparatus outputs onto any one type of the recording media among the pluralities of types of recording media the color images based on image data, and also outputs the result of the judgment of acceptance for the each type of the recording media used in a visually verifiable manner.

13. The image outputting method of claim 11, further comprising:
storing associated information to the result of the judgment while relating the information with the result of the judgment of acceptance; and
controlling so that, the image outputting apparatus outputs the associated information in a visually verifiable manner, in addition to outputting the result of the judgment of acceptance.

14. The image outputting method of claim 13, wherein the associated information comprises at least one of a date and time when the judgment of acceptance was made, the measured values used for the judgment, the reference values used for the judgment, and a value indicating a difference between the measured values used for the judgment and the reference values used for the judgment.

15. The image outputting method of claim 11, further comprising a selection inputting step for inputting a selection of whether or not to output the judgment result in a visually verifiable manner, wherein when the selection to output the judgment result has been inputted in the selection input step, the image outputting apparatus is controlled so that the apparatus outputs onto the recording medium the color images based on image data, and also outputs a result of the judgment of acceptance in a visually verifiable manner.

16. An image outputting method for outputting color images onto a recording medium based on image data, with a plurality of image outputting apparatuses, each apparatus of the plurality of image outputting apparatuses being installed at each location, the image outputting method comprising, at a control server connected through network to the each apparatus:
storing reference values of color characteristics stipulated for reference colors for each type of apparatus of the plurality of image outputting apparatuses;
receiving the measured values of the color characteristics of reference colors outputted by and sent from the each apparatus;
carrying out an acceptance judgment by comparing the respective measured values received with the reference values for the each type of apparatus stored;
storing a result of the acceptance judgment while relating the result with the each apparatus;
receiving, from a side of the each apparatus, an inquiry about the acceptance judgment result regarding the each apparatus; and
transmitting the judgment information indicating the acceptance judgment result for the each apparatus,
wherein, at the each apparatus of the plurality of image outputting apparatuses, the image outputting method comprises the step of outputting onto the recording medium the color images based on image data, and also outputting the result of the judgment of acceptance transmitted in a visually verifiable manner.

17. The image outputting method of claim 16, wherein the plurality of image outputting apparatuses output color images onto plural types of recording media based on the image data, the image outputting method further comprising:
storing reference values of color characteristics stipulated for each type of the recording media regarding the reference colors of the each type of apparatus;
receiving the measured values of the color characteristics of reference colors outputted on each type of the recording media, the type of apparatus, and the type of the recording media used for outputting the reference colors;
carrying out the acceptance judgment by comparing the respective measured values received with the reference values stored for each type of the recording media regarding the reference colors of the each type of apparatus;
storing the result of the acceptance judgment while relating the result with the each type of apparatus and the each type of the recording media;
receiving, from a side of each image outputting apparatus of the plurality of image outputting apparatuses, an inquiry about the result of acceptance judgment regarding the type of the recording media to be used for outputting by the each image outputting apparatus; and
transmitting the judgment information indicating the result of acceptance judgment inquired for the type of the recording media regarding the each image outputting apparatus.

18. The image outputting method of claim 16, further comprising:
storing associated information to the result of the acceptance judgment while relating the information with the result of the acceptance judgment; and
controlling so that, the image outputting apparatus outputs the associated information in a visually verifiable manner, in addition to outputting the result of the acceptance judgment.

19. The image outputting method of claim 18, wherein the associated information comprises at least one of a date and time when the judgment of acceptance was made, the measured values used for the judgment, the reference values used for the judgment, and a value indicating a difference between the measured values used for the judgment and the reference values used for the judgment.

20. The image outputting method of claim 16, further comprising a selection inputting step for inputting a selection of whether or not to output the judgment result in a visually verifiable manner, wherein when the selection to output the judgment result has been inputted in the selection input step, the image outputting apparatus is controlled so that the apparatus outputs onto the recording medium the color images based on image data, and also outputs a result of the judgment of acceptance in a visually verifiable manner.
